(19) United States
(12) Patent Application Publication
(10) Pub. No.: US 2019/0067514 A1
(43) Pub. Date: Feb. 28, 2019

(54) SEMICONDUCTOR LIGHT EMITTING ELEMENT AND MANUFACTURING METHOD THEREOF

(71) Applicant: EPILEDS TECHNOLOGIES, INC., TAINAN CITY (TW)

(72) Inventors: HSIN LIANG YEH, Kaohsiung City (TW); MING-SEN HSU, TAINAN CITY (TW)

(21) Appl. No.: 15/901,906

(22) Filed: Feb. 22, 2018

(30) Foreign Application Priority Data
Aug. 24, 2017 (TW) 106128772

(51) Int. Cl. H01L 33/00; H01L 21/683

(52) U.S. Cl. CPC H01L 33/0095; H01L 33/0079; H01L 2221/68381; H01L 2221/68363; H01L 21/6836

(57) ABSTRACT

The present disclosure comprises a semiconductor light emitting element and a manufacturing method thereof. In the method, a light emitting element layer is firstly formed on an epitaxial substrate, and then a bonding adhesive is filled and a first substrate is bonded onto an upper surface of the light emitting element layer. Further, the epitaxial substrate is removed to expose a lower surface of the light emitting element layer and a second substrate is disposed on the lower surface. And further, the bonding adhesive is dissolved to remove the first substrate, and the light emitting element layer is finally cut together with the second substrate to form a plurality of semiconductor light emitting elements. The epitaxial substrate is replaced with the second substrate to solve the problem in which the substrate may be broken or warped during separation of the semiconductor light-emitting elements.

### CROSS-REFERENCE TO RELATED APPLICATION

This application claims priority to and the benefit of Taiwan Patent Application No. 106128772, filed on Aug. 24, 2017, at the Taiwan Intellectual Property Office, the entire contents of which are herein incorporated by reference in their entirety.

### BACKGROUND OF THE INVENTION

### 1. Field of the Invention

The present invention relates to a method for manufacturing a semiconductor light-emitting element. In particular, the present invention relates to a method of replacing an epitaxial substrate to facilitate manufacture of a micro-semiconductor light-emitting element and a semiconductor light-emitting element thereof.

### 2. Description of the Related Art

The semiconductor light emitting diode (LED) is one of the best available sources for providing the most effective light currently. In a semiconductor light emitting diode, the plurality of semiconductor light-emitting elements are formed on the epitaxial substrates, and then separated from each other together with the epitaxial substrates respectively to form the respective semiconductor light-emitting elements.

However, the conventional method for separating the semiconductor light-emitting element is limited to the material properties of the substrate when the micro-semiconductor light-emitting elements are separated, and the surface of connecting the semiconductor light-emitting elements with the substrate materials are often broken or warped during separating the semiconductor light emitting elements and thus it cannot effectively satisfy the demand for increasing yield rates of mass production.

The inventors of the present invention have designed a method for manufacturing semiconductor light-emitting elements to improve the aforementioned shortcomings of the prior art so as to promote industrial practicability.

### SUMMARY OF THE INVENTION

In view of the above-mentioned problems of the conventional art, the object of the present invention is to provide a method for manufacturing semiconductor light-emitting element to solve the above problems of the conventional manufacturing methods.

One object of the present invention is to provide a method for manufacturing a semiconductor light-emitting element, comprising: providing an epitaxial substrate; forming a light-emitting element layer on the epitaxial substrate; attaching a first substrate onto an upper surface of the light emitting element layer via a bonding adhesive; removing the epitaxial substrate to expose a lower surface of the light-emitting element layer; bonding a second substrate on the lower surface of the light-emitting element layer; dissolving the bonding adhesive to remove the first substrate; and cutting the light-emitting element layer together with the second substrate to form a plurality of semiconductor light-emitting elements respectively.

Preferably, the first substrate comprises a silicon substrate or a glass substrate.

Preferably, the light-emitting element layer has a concave-convex structure on the upper surface thereof, and the step of attaching the first substrate onto the upper surface of the light emitting element layer comprises coating the bonding adhesive for covering and filling the upper surface of the light-emitting element layer such that the bonding adhesive is formed to have a flat top surface.

Preferably, the step of removing the epitaxial substrate comprises applying a laser on a connecting surface of the epitaxial substrate and the light-emitting element layer to break a connecting structure between the epitaxial substrate and the light-emitting element layer.

Preferably, the step of disposing the second substrate comprises increasing a temperature of a bonding surface between the second substrate and the light-emitting element layer such that they are bonded to each other, or coating a bonding material for connecting the second substrate with the light-emitting element layer.

Preferably, the step of dissolving the bonding adhesive comprises changing an ambient temperature to reduce the viscosity of the bonding adhesive.

Preferably, the bonding adhesive is an ultraviolet-curable adhesive and the step of dissolving the bonding adhesive comprises using an infrared light to dissolve the bonding adhesive.

Preferably, the step of dissolving the bonding adhesive comprises applying at least two outward forces to physically delaminate the light-emitting element layer from the bonding adhesive.

Preferably, the step of cutting the light-emitting element layer and the second substrate comprises application of a laser to cut the light-emitting element layer and the second substrate according to the distribution of the semiconductor light-emitting elements.

The object of the present invention is also to provide a semiconductor light-emitting element, comprising: a substrate; a light-emitting element layer disposed on the substrate and comprising a P-type semiconductor layer and a N-type semiconductor layer; a p-type electrode disposed on the light-emitting element layer and exposed on an upper surface of the light-emitting element layer, the P-type electrode is electrically connected to the P-type semiconductor layer; and a N-type electrode disposed on the light-emitting element layer and exposed on the upper surface of the light-emitting element layer, the N-type electrode is electrically connected to the N-type semiconductor layer; wherein the crystal lattices of the substrate and the crystal lattices of a lower surface of the light-emitting element layer are mismatched with respect to each other.

According to the method for manufacturing semiconductor light-emitting element of the present invention, the bonding adhesive and the first substrate are coated on the light-emitting element layer before separating the epitaxial substrate to improve the component intensity of the semiconductor light-emitting element when the epitaxial substrate is delaminated.

Furthermore, the second substrate is disposed after separating the epitaxial substrate to improve the structural strength of the semiconductor light-emitting element in the process for separating the semiconductor light-emitting element.

### BRIEF DESCRIPTION OF THE DRAWINGS

The aforementioned and other features and advantages of the present invention will become apparent according to the exemplary embodiments described in more detail with reference to the accompanying drawings in which:

FIG. 1 is a flowchart of a method for manufacturing semiconductor light-emitting element.

FIG. 2A illustrates an exemplary embodiment of a semiconductor structure where a light-emitting element layer is formed on an epitaxial substrate.

FIG. 2B illustrates an exemplary embodiment of a semiconductor structure where a bonding adhesive is filled and a first substrate is attached on a light-emitting element layer.

FIG. 2C illustrates an exemplary embodiment of a semiconductor structure where an epitaxial substrate is removed from a lower surface of a light-emitting element layer.

FIG. 2D illustrates an exemplary embodiment of a semiconductor structure where a second substrate is attached on a lower surface of a light-emitting element layer.

FIG. 2E illustrates an exemplary embodiment of a semiconductor structure where a bonding adhesive is dissolved from an upper surface of a light-emitting element layer to remove a first substrate.

FIG. 2F illustrates an exemplary embodiment of a semiconductor light-emitting element of the present invention.

### DETAILED DESCRIPTION OF THE PREFERRED EMBODIMENTS

For a better understanding of the features, contents and advantages of the present invention, and the effect that may be achieved therefrom, the present embodiments of the present invention are described in more detail as follows with reference to the accompanying drawings. It should be noted that the drawings are used for the purpose of illustrating and assisting the specification, without necessarily implying the actual ratio and the precise configuration. Therefore, in the accompanying drawings, the ratio and the configuration shall not be interpreted in any way that limits the claims of the present invention in the practical implementation.

As used herein, “and/or” term comprises any or all combinations of one or more related items. When an element list is preceded by the description of “at least one”, the all elements rather than the individual element in the list are modified.

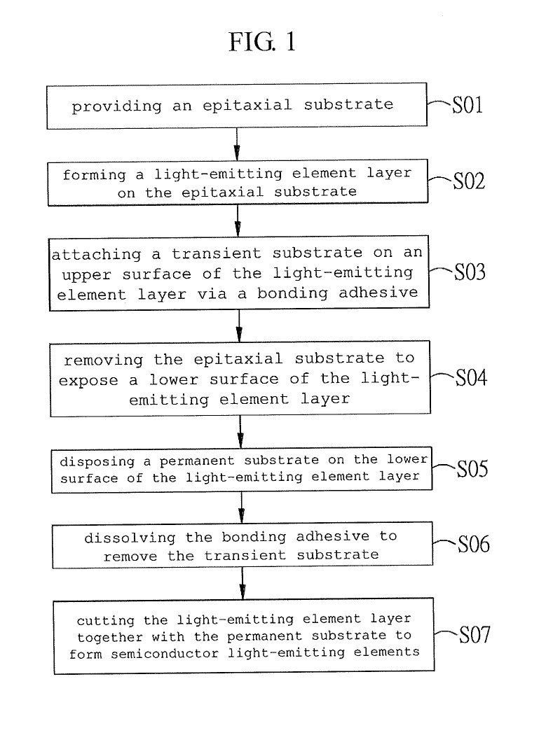

Referring to FIG. 1, which is a flowchart of a method for manufacturing semiconductor light-emitting element and an exemplary embodiment of a stacked structure of a method for manufacturing semiconductor light-emitting element of the present invention.

The present invention will be sequentially described in detail as follows: an embodiment of the present invention provides a method for manufacturing a semiconductor light-emitting element, which replaces the epitaxial substrate of the semiconductor before cutting the semiconductor light-emitting element. The method of the present invention may be suitable for the requirements of production flow in mass production for such a semiconductor light emitting element and is not limited to the structure type of the semiconductor light emitting element:

The method of the present invention comprises the following steps:

At the step S01: providing an epitaxial substrate 10, which may preferably be a sapphire substrate.

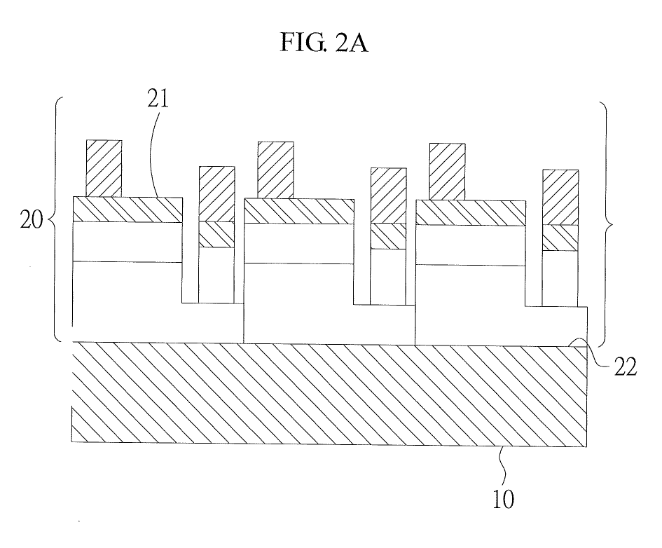

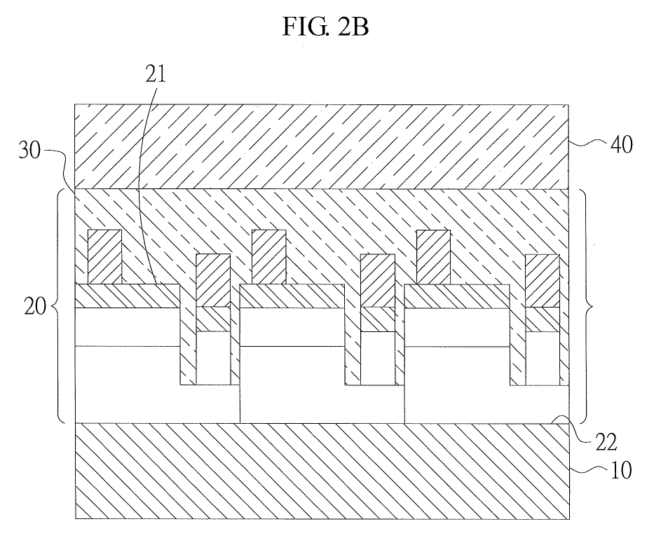

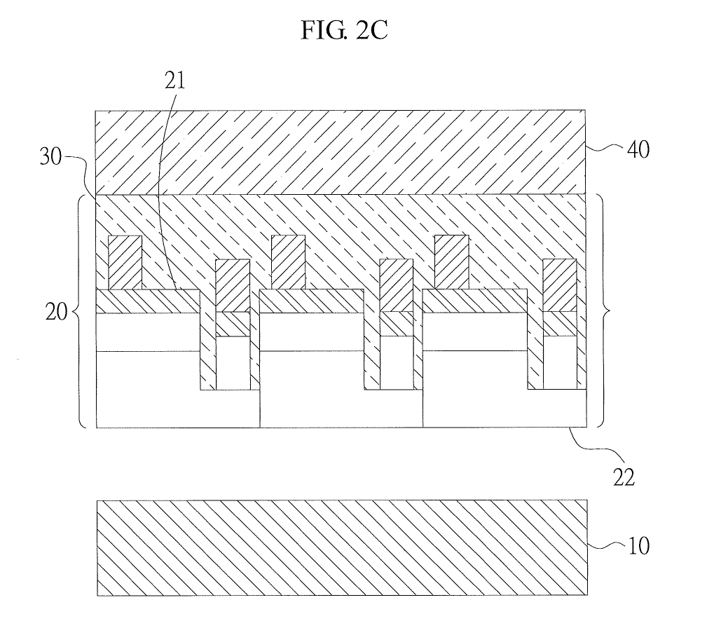

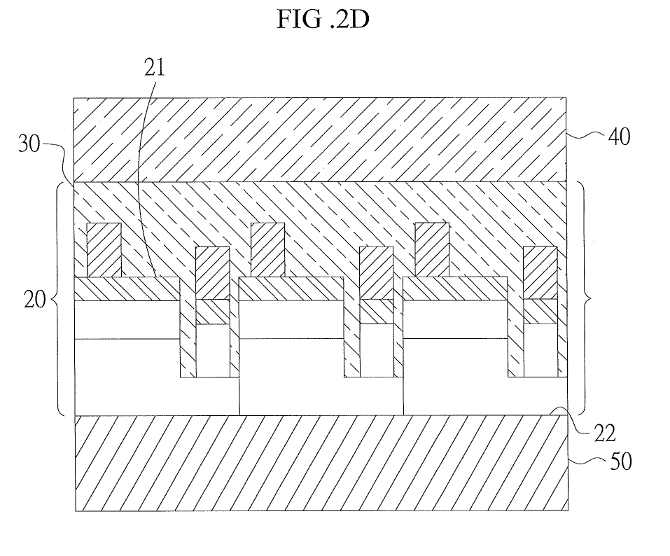

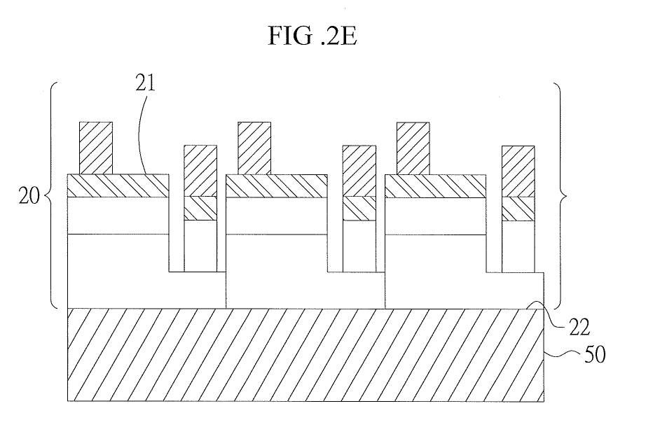

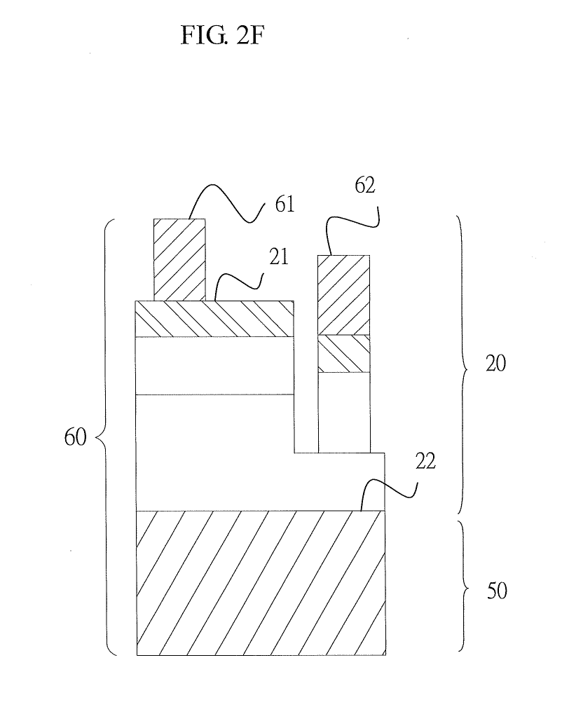

At the step S02: forming a light-emitting element layer 20 on the epitaxial substrate 10, as shown in FIG. 2A, the light-emitting element layer 20 formed on the epitaxial substrate 10 has an upper surface 21 and a lower surface 22 bonded to the epitaxial substrate 10. For example, the step of forming the light-emitting element comprises forming oxide composition on the epitaxial substrate 10; forming a first oxide crystal composition, wherein an amorphous component is left over a surface of the oxide by a heat treatment; and stacking a second oxide crystal composition on the first oxide crystal composition, wherein the second oxide crystal composition is formed by using the same material as the first oxide crystal composition and growing homologous crystals.

The method for manufacturing another semiconductor light-emitting element of the present invention comprises the following steps: forming oxide composition on the epitaxial substrate 10; forming a first oxide crystal composition which grows from the surface of the oxide component to the inside and leaves an amorphous component above the surface of the base component; and stacking a second oxide crystal composition on the first oxide crystal composition, wherein the second oxide crystal composition is formed by using a material that is different from that of the first oxide crystal composition and growing heterogeneous crystals.

In the each aforementioned manufacturing method, the first oxide crystal composition and the second oxide crystal composition have high purity and have inherent conductive characteristics.

The all oxide crystal compositions and oxide compositions are metal oxides, which may be selected from four-component metal oxides such as In—Sn—Ga—Zn—O, three-component metal oxides such as In—Ga—Zn—O, In—Sn—Zn—O, In—Al—Zn—O, Sn—Ga—Zn—O, Al—Ga—Zn—O or Sn—Al—Zn—O, two-component metal oxides such as In—Zn—O, Sn—Zn—O, Al—Zn—O, Zn—Mg—O, Sn—Mg—O or In—Mg—O, or one-component metal oxides such as In—O, Sn—O or Zn—O. For example, In—Sn—Ga—Zn—O represents an oxide containing indium (In), tin (Sn), gallium (Ga) and zinc (Zn), and the stoichiometric ratio thereof is not particularly limited.

The oxide crystal composition and the oxide composition may be represented by InMO₃ (ZnO) m (m>0, and m is not a natural number). Here, M represents one or more metal elements selected from Ga, Al, Mn and Co. For example, M may be Ga, Ga and Al, Ga and Mn, Ga and Co, etc.

Furthermore, an oxide semiconductor material represented by In-A-B-O may be used. Here, A represents one or more elements selected from the groups consisting of the group 13 elements such as gallium (Ga) or aluminum (Al) and the group 14 elements including silicon (Si) or germanium (Ge). In addition, B represents one or more elements selected from the group 12 elements. The contents of In, A and B may be set freely, and the content of A may be 0. On the other hand, the content of In and the content of B may not be 0. In other words, In—Ga—Zn—O, In—Zn—O, etc. are contained as described above.

Preferably, the number of oxide layers and the oxide components included in the formed light-emitting element layer 20 may be adjusted depending on the purpose, the upper surface 21 of the light-emitting element layer 20 that includes the P-type electrode and the N-type electrode is finally exposed on the formed light-emitting element layer 20.

At the step S03: attaching a first substrate 40 on the upper surface 21 of the light-emitting element layer 20 via a bonding adhesive 30; the light-emitting element layer 20 on the epitaxial substrate 10 is shown in FIG. 2B, wherein the upper surface 21 of the light-emitting element layer 20 may have a concave-convex structure formed by the guiding channels which facilitate the subsequent cutting between the formed LEDs. At this step, the bonding adhesive 30 is coated on the concave-convex structure and formed to have a top surface which is formed flat, and then the flat-formed top surface is bonded to the first substrate 40. The flat-formed top surface may attach the first substrate 40 onto the light-emitting element layer 20 coated with the bonding adhesive 30 and be formed in accordance with the surface shape of the first substrate 40. Preferably, the attached first substrate 40 is constituted of a silicon substrate material having a thermal expansion coefficient of 2.6×10⁻⁶/K, 20° C. and a density of 2.33 g/cc. Further, preferably, the attached first substrate 40 is constituted of a glass material having a thermal expansion coefficient of 5.52×10⁻⁷/K, 25° C. and a density of 2.18 g/cm³. Further, the coated bonding adhesive 30 may be selected from the different materials depending on the application thereof, such as a ultraviolet-curable adhesive (UV glue), a cooling glue, a pyrolysis glue, a double-sided glue, etc.

At the step S04: removing the epitaxial substrate 10 to expose the lower surface 22 of the light-emitting element layer 20; as shown in FIG. 2C, a connecting surface of the epitaxial substrate 10 and the light-emitting element layer 20 is broken in a separation manner such that the epitaxial substrate 10 and the light-emitting element layer 20 are separated from each other. Further, the step of removing the epitaxial substrate 10 may comprise cutting the connecting surface of the epitaxial substrate 10 and the light-emitting element layer 20 with a laser to break the connection between the epitaxial substrate 10 and the light-emitting element layer 20.

At the step S05: disposing a second substrate 50 on the lower surface 22 of the light-emitting element layer 20; as shown in FIG. 2D, wherein the step of disposing the second substrate 50 comprises increasing a temperature of the bonding surface between the second substrate 50 and the light-emitting element layer 20 such that they are bonded to each other, or coating a bonding material on the bonding surface to connect the second substrate 50 with the light-emitting element layer 20. Further, the material constituting the second substrate 50 comprises a material having a high weather resistance, a high water resistance, a high gas barrier property, a high transmittance, a high refractive index and a high light extraction performance, such as an epoxy resin, etc.; alternatively, a material having a high and low temperature stability, a high weather resistance, a high adhesiveness, a high shock-absorbing or a cushioning property, a high dielectric property, a high transmittance rate, and a high chemical stability and reliability, included in such materials as silicon, etc.

At the step S06: dissolving the bonding adhesive 30 to remove the first substrate 40, which is carried out by dissolving the connection between the bonding adhesive 30 and the light-emitting element layer 20, as shown in FIG. 2E, thereby dissolving the bonding adhesive 30 from the first substrate 40 bonded to the bonding adhesive 30 to expose the upper surface 21 of the light-emitting element layer 20. This step may reduce the viscosity of the bonding adhesive 30 and the light-emitting element layer 20 in various manners depending on the type of the used bonding adhesive, for example, in the manner of changing the ambient temperature such that the viscosity of the bonding adhesive 30 and the light-emitting element layer 20 is reduced in the cold or pyrolysis manner for the bonding adhesives having the viscosity varied with the temperatures. Alternatively, if the bonding adhesive 30 is an ultraviolet-curable adhesive, an infrared light may be applied to the connecting surface between the bonding adhesive 30 and the upper surface 21 of the light-emitting element layer 20 to dissolve the bonding adhesive 30 from the light-emitting element layer 20. Yet alternatively, if using a double-sided glue as the bonding adhesive 30, at least two outward forces may be directly applied to physically delaminate the light-emitting element layer 20 from the bonding adhesive 30.

At the step S07: cutting the light-emitting element layer 20 together with the second substrate 50 to form a semiconductor light-emitting element 60; wherein, a guiding channel may be formed on the upper surface 21 of the light-emitting element layer 20 to guiding to cut the light-emitting element layer 20 into the separated semiconductor light-emitting elements 60, as shown in FIG. 2F. For example, the light-emitting element layer 20 and the second substrate 50 may be cut according to the layout of the semiconductor light-emitting element 60 by using a laser. It is worth noting that a material difference of the selected second substrate 50 and the epitaxial substrate 10 such as an epoxy resin substrate or a silicon substrate with respect to a sapphire substrate such that the semiconductor light-emitting element 60 is more easily cut into a smaller size, for example, its length and width may be between 20 microns and 50 microns.

According to the object of the present invention, as shown in FIG. 2F, forming a semiconductor light-emitting element 60, which comprises a substrate (that is the second substrate 50 shown in FIG. 2A to FIG. 2E); a light-emitting element layer 20 disposed on the substrate and including a P-type semiconductor layer and a N-type semiconductor layer; a P-type electrode 61 disposed on the light-emitting element layer 20, exposed on an upper surface 21 of the light-emitting element layer 20 and electrically connected to the P-type semiconductor layer; and a N-type electrode 62 disposed on the upper surface 21 of the light-emitting element layer 20, exposed on a top surface of the light-emitting element layer 20 and electrically connected to the N-type semiconductor layer, wherein, the crystal lattices of the second substrate 50 and a lower surface 22 of the light-emitting element layer 20 are mismatched with respect to each other.

In summary, according to the method for manufacturing a semiconductor light-emitting element of the present invention, the bonding adhesive 30 and the first substrate 40 are coated on the upper surface 21 of the light-emitting element layer 20 before separating the epitaxial substrate 10 to improve the component intensity of the semiconductor light-emitting element 60 when the epitaxial substrate 10 is delaminated. Further, the second substrate 50 is disposed after separating the epitaxial substrate 10 to reinforce the component strength in the process for cutting the semiconductor light-emitting element layer 20 to prevent the cutting surface from being broken or warped and the formed semiconductor light-emitting element 60 from being broken.

The above-described embodiments are merely an exemplary illustration, and the present invention is not limited thereto. Any equivalent modification or change may be made thereto without departing from the scope and the spirit of the present invention and is covered by the appended claims.

What is claimed is:

1. A method for manufacturing a semiconductor light-emitting element, comprising:
providing an epitaxial substrate;
forming a light-emitting element layer on the epitaxial substrate;
attaching a first substrate onto an upper surface of the light emitting element layer via a bonding adhesive;
removing the epitaxial substrate to expose a lower surface of the light-emitting element layer;
disposing a second substrate on the lower surface;
dissolving the bonding adhesive to remove the first substrate; and
cutting the light-emitting element layer together with the second substrate to form a plurality of semiconductor light-emitting elements.

2. The method for manufacturing a semiconductor light-emitting element of claim 1, wherein the first substrate comprises a silicon substrate or a glass substrate.

3. The method for manufacturing a semiconductor light-emitting element of claim 1, wherein the light-emitting element layer has a concave-convex structure on the upper surface thereof, and the step of attaching the first substrate onto the upper surface of the light emitting element layer via the bonding adhesive comprises coating the bonding adhesive for covering and filling the upper surface of the light-emitting element layer such that the bonding adhesive is formed to have a flat top surface.

4. The method for manufacturing a semiconductor light-emitting element of claim 1, wherein the step of removing the epitaxial substrate comprises applying a laser on a connecting surface of the epitaxial substrate and the light-emitting element layer to break a connecting structure between the epitaxial substrate and the light-emitting element layer.

5. The method for manufacturing a semiconductor light-emitting element of claim 1, wherein the step of disposing the second substrate comprises increasing a temperature of a bonding surface between the second substrate and the light-emitting element layer such that they are bonded to each other, or coating a bonding material for connecting the second substrate with the light-emitting element layer.

6. The method for manufacturing a semiconductor light-emitting element of claim 1, wherein the step of dissolving the bonding adhesive comprises changing an ambient temperature to reduce the viscosity of the bonding adhesive.

7. The method for manufacturing a semiconductor light-emitting element of claim 1, wherein the bonding adhesive is an ultraviolet-curable adhesive and the step of dissolving the bonding adhesive comprises using an infrared light to dissolve the bonding adhesive.

8. The method for manufacturing a semiconductor light-emitting element of claim 1, wherein the step of dissolving the bonding adhesive comprises applying at least two outward forces to physically delaminate the light-emitting element layer from the bonding adhesive.

9. The method for manufacturing a semiconductor light-emitting element of claim 1, wherein the step of cutting the light-emitting element layer and the second substrate comprises applying a laser to cut the light-emitting element layer and the second substrate according to the distribution of the semiconductor light-emitting elements.

10. A semiconductor light-emitting element, comprising:
a substrate;
a light-emitting element layer disposed on the substrate, the light-emitting element layer comprises a P-type semiconductor layer and a N-type semiconductor layer;
a P-type electrode disposed on the light-emitting element layer and exposed on an upper surface of the light-emitting element layer, the P-type electrode is electrically connected to the P-type semiconductor layer; and
a N-type electrode disposed on the light-emitting element layer and exposed on the upper surface of the light-emitting element layer, the N-type electrode is electrically connected to the N-type semiconductor layer;
wherein the crystal lattices of the substrate and the crystal lattices of a lower surface of the light-emitting element layer are mismatched with respect to each other.
